(19) United States
(12) Patent Application Publication
(10) Pub. No.: US 2020/0373450 A1
(43) Pub. Date: Nov. 26, 2020

(54) SURFACE STRUCTURE FOR OPTICAL ABSORPTION IN LIGHT ABSORPTION DEVICES

(71) Applicant: B. G. NEGEV TECHNOLOGIES AND APPLICATIONS LTD., AT BEN-GURION UNIVERSITY, Beer-Sheva (IL)

(72) Inventor: Gil SHALEV, Ramat HaSharon (IL)

(21) Appl. No.: 16/992,687

(22) Filed: Aug. 13, 2020

Related U.S. Application Data
(63) Continuation-in-part of application No. PCT/IL2019/050551, filed on May 15, 2019.
(60) Provisional application No. 62/885,839, filed on Aug. 13, 2019.
(60) Provisional application No. 62/671,448, filed on May 15, 2018.
(60) Provisional application No. 62/795,582, filed on Jan. 23, 2019.
(60) Provisional application No. 62/795,580, filed on Jan. 23, 2019.

(51) Int. Cl. H01L 31/054

(52) U.S. Cl. CPC H01L 31/0543

(57) ABSTRACT

The invention relates to an array for absorbing light radiation, which comprises a plurality of subwavelength inverted cones that are arranged on a layer, each cone having a curved sidewall in cross-section

This application is a Continuation-in-Part of International Application No. PCT/IL2019/050551 filed May 15, 2019, which claims the benefit of U.S. Provisional Application Nos. 62/671,448 filed May 15, 2018, 62/795,582 filed Jan. 23, 2019, and 62/795,580 filed Jan. 23, 2019. This application also claims the benefit of U.S. Provisional Application No. 62/885,839 filed Aug. 13, 2019, the entire contents of each of which are hereby incorporated by reference.

### FIELD OF THE INVENTION

The field of the invention relates in general to a multi-body structure for a front array in optical absorption-based and photonic devices. In one example, the invention relates to a front array for use in an array of photovoltaic cells.

### BACKGROUND OF THE INVENTION

Light trapping and broadband absorption of solar radiation is of interest to various absorption-based photonic applications ranging from optical sensing to solar energy conversion.

Non-imaging optics was developed by Winston and colleagues during the late 1960s and early 1970s, in which they realized that the performance of light collection systems (in terms of collecting aperture and the angular field of view) could be improved if one is to leap beyond the physics of geometrical image-forming optics. In other words, while an imaging system is required to conserve space-phase volume when mapping each point in the object plane to the image plane, a non-imaging system obeys the conservation of space-phase volume solely by mapping the edge of all the rays (the edge-ray principle). Soon after, it was realized that non-imaging optics has important applications for the collection and concentration of the solar radiation.

Photovoltaic cells are typically embedded in a semiconductor layer to produce a solar panel. In general, the amount of layer's material (for example, Silicon) significantly contributes to the costs. A reduction of the thickness of the layer could have reduced these material costs, however, it has been so far found that the use of a Silicon layer with a thickness less than about 500 μm is substantially impractical, as the amount of absorbed photons in such a thinner layer is insufficient, as below some thickness, the layer becomes substantially “transparent” to the incoming radiation, namely, the radiation practically passes through the layer with very little, if at all, photon trapping within the layer.

In another aspect, a Silicon-On-Insulator (SOI) is a semiconductor fabrication technique that uses pure crystal silicon and silicon oxide for integrated circuits and microchips. This technique is widely used today for a variety of applications, such as, Internet of Things, memories, processors, photonic devices, sensors, etc. The SOI wafer typically comprises three layers: a Silicon layer, a buried oxide (BOX)layer, and a handle layer, while the Silicon layer, whose thickness is in the order of few μm, is the only active layer (this layer is also referred to as the “SOI layer” or “SOI film”—hereinafter, the terms “film” and “layer” are used interchangeably). While the prior art has applied photovoltaic cells within a SOI, the very thin layer of only few μm could not provide electrical power. More specifically, currently the photovoltaic cells on SOI wafers can support only photovoltage, with substantially no current, in view of the very thin SOI film, which is well below wavelength of light.

The Yablonovitch limit predicts the maximal light-trapping in a homogeneous semiconducting layer, which becomes possible by randomization of the top and bottom interfaces of the film. This randomization results in a generation of wave vectors that can occupy the layer's various optical modes that are otherwise not accessible to the impinging illumination.

It is also known in the art that the absorption of the solar radiation is increased when a surface with irregularities is used, compared to the use of a smooth film (undecorated thin film). Surface texturing with ordered or disordered arrays of subwavelength (or up to about the size of the wavelength) semiconducting bodies, for example, an array of subwavelength nanopillars (NPs), each pillar having several hundred nanometers in diameter, was demonstrated experimentally and numerically to produce a broader band of solar radiation absorption, with improved efficiency in light (photons) trapping by this array.

Shalev et. al. “Enhanced photovoltaics inspired by the fovea centralis” Sci. Reports, 5, 8570 (2015) (hereinafter referred to as “Shalev 2015”), has suggested the use of a sub-wavelength array of inverted cones (“light funnels”, hereinafter, LFs). The term “inverted cones” is used herein to indicate that the larger base of the truncated cone faces the incoming radiation. The fabrication of the arrays of LFs was also demonstrated. Shalev has demonstrated that an array of LFs exhibits an improved absorption efficiency of 65% compared to a smooth film (undecorated thin film), while a similar array of NPs provides an improvement of only 36.6% compared to a smooth film.

While it was shown that the use of LFs improves the absorption efficiency of the array compared to an array of NPs, and even more compared to a smooth film, there is still a necessity for a better structure, that will further increase the efficiency of solar energy harvesting per given area of an array of photovoltaic cells.

Compound Parabolic Concentrators (CPCs) are non-imaging structures that are known to be advantageous in the art of solar radiation concentration. A 2D CPC is in fact a body structure whose sidewall in cross section is defined by two parabolas that share a common focal point. A 3D CPC is a revolution of this 2D CPC. However, in the prior art these bodies have always been used in sizes many orders larger than the wavelength of light. For example, CPCs having a height of, for example 3 mm or larger are used in the art. Furthermore, these prior art CPCs can be used in a single unit or multiple units, where the effect of a single unit is multiplied by the number of units, when a plurality of units are used.

It is therefore an object of the present invention to provide an array of surface nanostructures that provides an increased optical absorption and photocurrent (and efficiency) compared to the prior art.

It is another object of the present invention to provide such an array of surface nanostructures for use in photovoltaic cells.

It is still another object of the present invention to provide a new structure for optical absorption, which can be used in various optical devices, such as sensors, optical switches, and other absorption-based optical devices.

It is still another object of the present invention to provide such an array of surface nanostructures that can provide a broadband harvesting of solar energy.

It is still another object of the present invention to provide an SOI-fabricated solar cell structure that is capable of efficiently producing solar power.

It is still another object of the present invention to provide an array of surface nanostructures for anti-transmission layer, either broadband or spectrally.

It is still another object of the present invention to provide an array of surface nanostructures for absorption-based optical devices whose light absorption is optimized for specific spectral ranges.

It is still another object of the present invention to provide such an array of surface nanostructures, that can produce absorption enhancement in an underlined substrate.

Other objects and advantages of the invention will become apparent as the description proceed.

### SUMMARY OF THE INVENTION

The invention relates to an array for absorbing light radiation, which comprises a plurality of subwavelength inverted cones that are arranged on a layer, each cone having a curved sidewall in cross-section (hereinafter also referred to briefly as “cone having a curved sidewall”).

In an embodiment of the invention, the array is used in an absorption-based optical device.

In an embodiment of the invention, each of the cones is a truncated cone which is inverted such that its wider base faces the incoming radiation.

In an embodiment of the invention, the curved sidewall is convex.

In an embodiment of the invention, the convex sidewall has a compound parabolic body shape.

In an embodiment of the invention, the convex sidewall has a parabolic shape.

In an embodiment of the invention, the curved sidewall is concave.

In an embodiment of the invention, the curved concave sidewall has a trumpet-like shape.

In an embodiment of the invention, the period between the cones is in the subwavelength light range.

In an embodiment of the invention, a period between the cones is substantially in the order of a wavelength of an impinging illumination.

In an embodiment of the invention, the array is fabricated from a semiconductor material.

In an embodiment of the invention, the semiconductor material is selected from Silicon, GaAs, or Germanium.

In an embodiment of the invention, each of the cones, together with the layer, forms a photovoltaic cell.

In an embodiment of the invention, the array is configured to absorb radiation in a specific spectrum or wavelength of light.

In an embodiment of the invention, the array configured to a limited range of spectral radiation.

In an embodiment of the invention, the array is fabricated from a dielectric material, said array causing an absorption of radiation in an underlying layer made from a semiconductor material.

In an embodiment of the invention, the array further comprises an anti-reflection coating.

The invention also relates to an SOI structure for absorbing light radiation, the structure comprising within a Silicon layer in the structure an array of a plurality of subwavelength inverted cones.

In an embodiment of the invention, the SOI structure further comprises an insulating buried oxide layer and a handle layer.

The invention also relates to an absorption-based optical device, which comprises an array for absorbing light radiation, the array comprising a plurality of subwavelength inverted cones that are arranged on a layer, each cone having a curved sidewall in cross-section.

In an embodiment of the invention, the absorption-based optical device is configured to absorb broadband light.

In an embodiment of the invention, the absorption-based optical device further comprises a filter to limit the absorption to a specific spectrum or wavelength of light.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

In the drawings:

FIG. 1a illustrates a structure of a prior art layer for a broadband absorption of light radiation;

FIG. 1b shows a single truncated cone of the array of FIG. 1a in a simplified cross-section view;

FIG. 2a shows a schematic structure of an array of subwavelength compound parabolic bodies (henceforth a CPB array), according to an embodiment of the present invention;

FIG. 2b shows a single CPB of the array of FIG. 2a in a simplified cross-section view;

FIG. 3a shows the relative spectral absorption of a CPB array, a nanopillar (NP) array, a smooth film, and the Yablonovitch limit, each having a height of 0.5 μm;

FIG. 3b shows the relative spectral absorption of a CPB array, a nanopillar (NP) array, a smooth film, and the Yablonovitch limit, each having a height of 1 μm;

FIG. 4 shows a spectral absorption comparison between arrays having different body shapes;

FIG. 5 shows a broadband absorption efficiency comparison between arrays containing various shapes of bodies;

FIG. 6a shows a schematic structure of an array of subwavelength hyperboloids (henceforth a trumpet array), according to an embodiment of the present invention;

FIG. 6b shows a single hyperboloid of the array of FIG. 6a in a simplified cross-section view;

FIG. 7a shows the relative spectral absorption of a a trumpet array, as compared to a smooth film (thin film), a nanopillar (NP) array, and to the Yablonovitch limit, each having a height of 0.5 μm;

FIG. 7b shows the relative spectral absorption of a trumpet array, as compared to a smooth film (thin film), a nanopillar (NP) array, and to the Yablonovitch limit, each having a height of 1 μm;

FIG. 8 schematically illustrates a general structure of a SOI device for absorbing light radiation, according to an embodiment of the present invention;

FIG. 9 shows absorption spectra, as realized on an SOI wafer, which includes a cone array according to an embodiment of the present invention;

FIG. 10a illustrates an LF array on top of an underlying substrate;

FIG. 10b presents an absorption-spectra of selected LF complex;

FIG. 10c shows the absorbed photon density (η_{γ,abs}) under the illumination of AM 1.5G solar radiation for both the LF and NP complexes;

FIG. 11a shows optical generation profiles along vertical axes of the NP and LF complexes under both J_{sc} and V_{oc} conditions;

FIG. 11b presents current-voltage (I-V) curves for an absorber acceptor doping level (NA) of 10¹⁸ cm⁻³ for both NP and LF photovoltaic cells;

FIG. 11c shows the dependency of J_{sc} and V_{oc} on N_{A} for different D_{b} values;

FIG. 11d presents a dependency of nominal power conversion efficiencies (nPCE) in various cases;

FIGS. 12a and 12b present energy band diagrams along the vertical axes of an LF cell and an NP cell, for N_{A}=10¹⁵ cm⁻³ and 10¹⁹=⁻³, respectively;

FIGS. 12c and 12d show Δnₑ profiles where for N_{A}=10¹⁵ cm⁻³ the densities are higher than for N_{A}=10¹⁹ cm⁻³ due to doping-dependent lifetimes;

FIGS. 12e and 12f show respective calculated spatially resolved V_{oc} profiles for a p-type absorber;

FIGS. 13a and 13b show energy band diagrams of NP and LF cells under J_{sc} conditions for N_{A}=10¹⁵ cm⁻³ and 10¹⁹ cm⁻³, respectively;

FIGS. 13c and 13d show respective nₑ which is linearly proportional to [symbol] ₑ;

FIGS. 13e and 13f show respective grad(ε_{fn}) for which it is positive, for different absorber dopings;

FIG. 14a illustrates a free-floating square-tiled silicon LF array;

FIG. 14b is a color map presenting the dependency of the absorptivity spectra on D_{b};

FIG. 14c shows the distribution of Δ_{ne,BB} for various values of D_{b};

FIG. 14d shows respective D_{b} dependent current density-voltage (J-V) curves for absorber doping level (Nₐ) of 10¹⁵ cm⁻³;

FIG. 15a shows the dependency of <Δn_{e,BB}> on P and D_{b}, for an LF PV cell;

FIG. 15b shows the respective V_{oc} values that were extracted from numerically calculated J-V curves;

FIG. 15c shows the spectrally-resolved V_{oc} and <Δₙₑ> for an NP PV cell and an LF PV cell for P=0.5, 0.7 and 2 μm for the indicated wavelengths;

FIG. 15d shows the spatial distribution of Δnₑ for the wavelengths marked in FIG. 15c;

FIG. 16a shows the D_{b} and P dependency of V_{oc} values that are extracted from the numerically-calculated J-V curves;

FIG. 16b shows N_{γ,abs,BB} corresponding to the results of FIG. 16a;

FIG. 16c shows <Δn_{e,BB}> corresponding to the results of FIGS. 16a and 16b;

FIG. 17a shows the absorptivity spectrum of a D_{b}=50 nm LF array with an underlying 200 nm substrate (H_{SUB});

FIG. 17b illustrates the LF PV cell and the NP PV cell, as well as respective numerically-calculated J-V curves for Nₐ=10¹⁵, 10¹⁷ and 10¹⁹ cm⁻³; and

FIG. 17c presents the extracted values of V_{oc}, J_{sc}, and nominal PCE (nPCE), assuming a unity filling factor.

### DETAILED DESCRIPTION OF THE INVENTION

As noted, Shalev et. al (2015) has suggested an array of inverted conical bodies as an optimized structure for broadband harvesting of solar energy. The conical bodies that were proposed are conventional mathematical truncated cones, whose sidewall in cross-section has straight-lines. As will be demonstrated hereinafter, the inventors have found that an improvement in broadband light absorption efficiency and/or enhanced spectral absorption, depending on specific parameters that are applied, can be obtained when truncated cones having curved sidewall lines in cross-section are used. The curved sidewalls of the cone bodies may relate to, for example, a Compound Parabolic Body, hereinafter “CPB” (a shape whose sidewall in 2D cross-section is a combination of two paraboloids having a common focal point. The 3D body is a revolution of the 2D cross-section. The shape of the CPB resembles the shape of prior art CPCs, however, the dimensions of the CPBs of the present invention are in the subwavelength range), ellipsoidal (paraboloid shape), spherical, hyperboloid, etc.

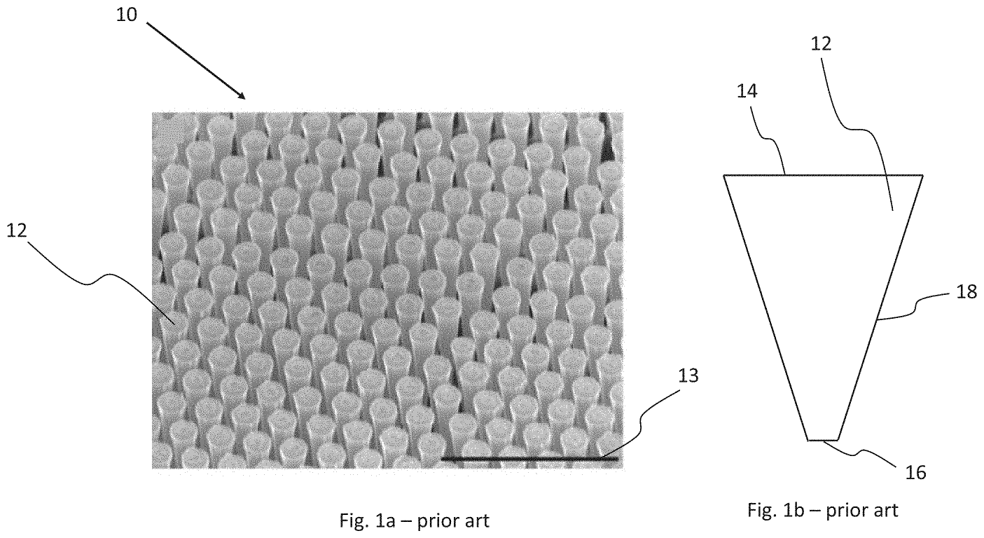

FIG. 1a illustrates a structure of a prior art layer for efficient and broadband absorption of light radiation, as disclosed in Shalev et. al. “Enhanced photovoltaics inspired by the fovea centralis” Sci. Reports, 5, 8570 (2015). The figure shows an image of a photovoltaic array 10, as scanned by a scanning electron microscope (SEM). The array was fabricated on a Silicon wafer having a thickness of about 500 μm using a low-cost fabrication techniques combining nanosphere lithography and Langmuir-Blodgett deposition of 1 mm polystyrene spheres. The scale bar 13 is 5 μm. The array 10 comprises a plurality of subwavelength truncated cones 12. FIG. 1b shows a single truncated cone 12 of the array of FIG. 1a in a simplified cross-section view. Each cone has a larger-diameter top base 14 (i.e., the base which faces the incoming radiation), a bottom base which is the base facing away from the incoming radiation, and a sidewall 18. As shown, conventional truncated cones were used, having a straight-line sidewall 18 in cross-section. In the example of FIG. 1a, the cones where arranged in a period (distance between centers of adjacent two cones) of 1 μm, while the top base 14 has a diameter Dₜ of 700 nm, and while the diameter D_{b} of the bottom base was selected to be 300 nm.

As shown in FIG. 1a, the inverted cones are arranged in a hexagonal tiling. The present invention, however, is not limited to any type of tiling.

The inventors have found that the use of subwavelength truncated cone bodies in the array, each having curved (concave or convex) sidewalls in cross-section is advantageous in variety of situations over the use of an array of truncated cone-bodies having straight-line side wall in cross-section (as in FIGS. 1a and 1b).

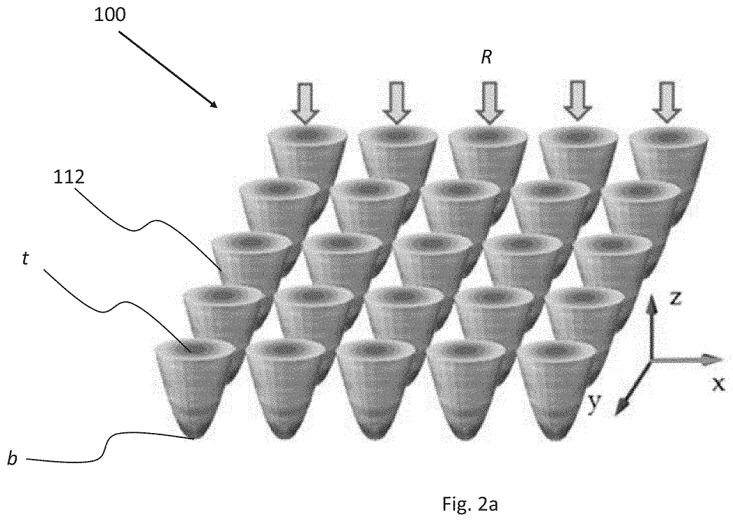

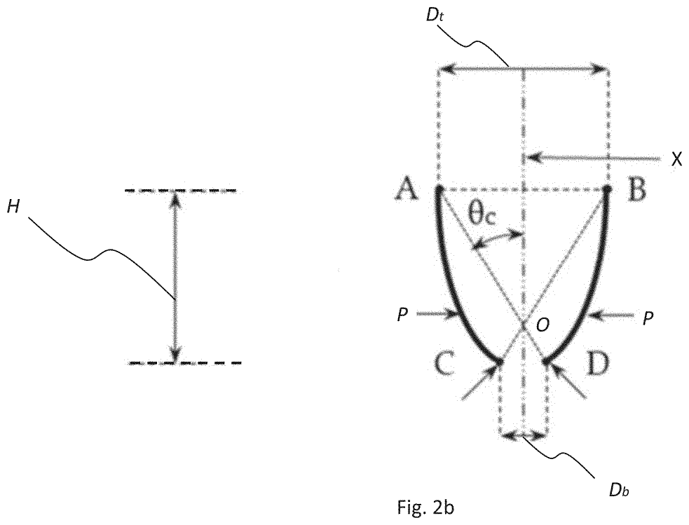

FIG. 2a shows a schematic structure of an array 100 of subwavelength compound parabolic bodies (hereinafter, CPBs). The CPBs are curved sidewall cones having a compound parabolic sidewall when viewed in cross section. The cones 112 are arranged in an array 100 of square-lattice arrangement such that their top base t faces the incoming radiation R, and their bottom base b faces away from the incoming radiation. A schematic simplified cross-section view of a single CPB cone is shown in FIG. 2b. Each of the cones 112 is a solid-filled body (not indicated in FIG. 2b), made, for example, of Silicon. The CPB cone has a top base having diameter Dₜ, a bottom base having a diameter D_{b} (D_{b} smaller than the diameter Dₜ) and a compound parabolic sidewall P which is defined by points ABCD. The sidewall of the compound parabolic body is in fact formed by two parabolas that share a same focal point O.

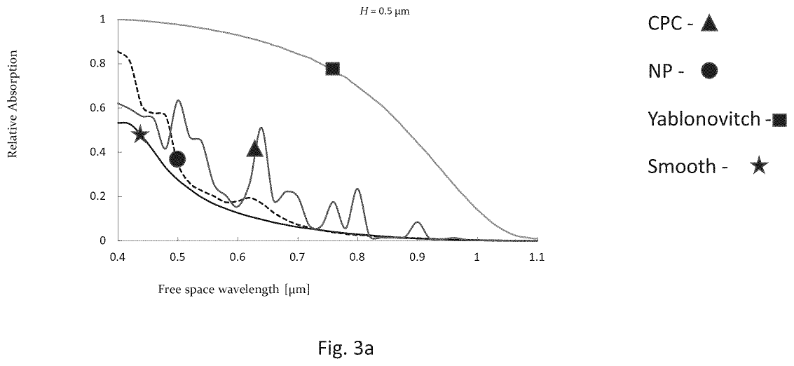

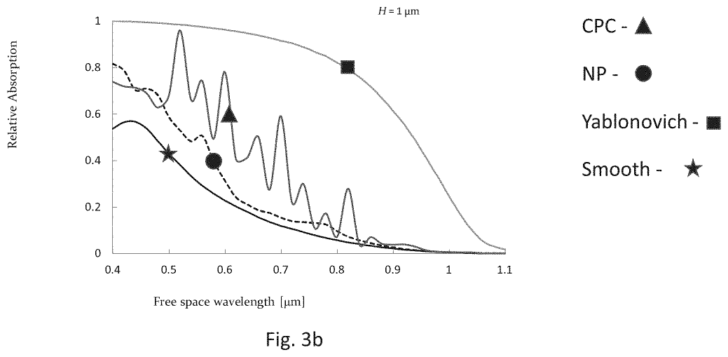

The inventors have performed several numerical calculations to investigate the absorption of subwavelength arrays that contain a variety of curved-cone (convex or concave) bodies. FIG. 3a shows the relative spectral absorption of a CPB array, a nanopillar (NP) array, a smooth film, and the Yablonovitch limit, each having a height of 0.5 μm. FIG. 3b shows the relative spectral absorption of a CPB array, a nanopillar (NP) array, a smooth film, and the Yablonovitch limit, each having a height of 1 μm. The CPB array included compound-parabolic bodies—heights of 0.5 μm (FIG. 3a) or 1 μm (FIG. 3b), with a top base diameter of 0.4 μm, and period of 0.5 μm. The bodies were arranged as shown in FIGS. 2a and 2b. The comparison was performed against an array of NP bodies, similarly having a height of either 0.5 μm or 1 μm and top diameter (Dₜ=400 nm), and having a same period. Evidently, the broadband absorption of the CPB array is significantly higher than that of either a smooth film or an NP array. The CPB array exhibits strong spectral absorption peaks. The Yablonovitch limit is also shown, and noticeably, while the NP array spectrum lies well below the limit, the spectra of the CPB array almost approach, for certain wavelengths, the Yablonovitch limit. The spectra approach closer to the Yablonovitch limit in the CPB array having 1 μm height bodies compared to the case where 0.5 μm bodies were used in the array.

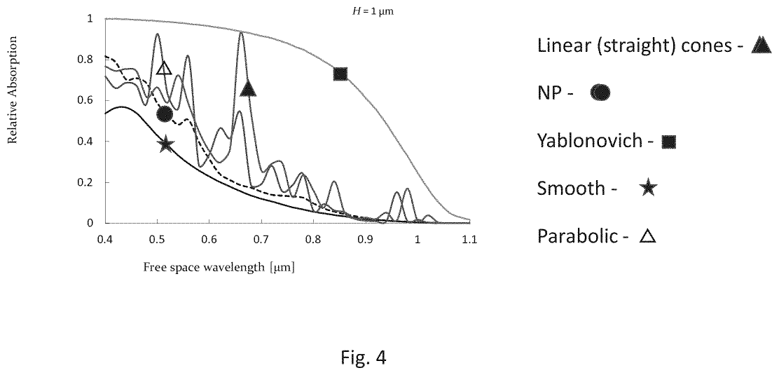

FIG. 4 shows a similar comparison for arrays having various other body shapes, with a height of 1 μm (other dimensions remain as before, unless specifically indicated). This diagram compares the absorption of arrays containing: (a) Linear cones (i.e., cones having straight sidewall lines in cross-section); (b) Nanopillar bodies; and (c) parabolic bodies. As before, the absorption of a smooth film, as well as the Yablonovitch limit are also shown. As can be seen, in the spectrum of between 0.5 μm-0.6 μm an array of parabolic bodies is superior over an array of linear-cones bodies.

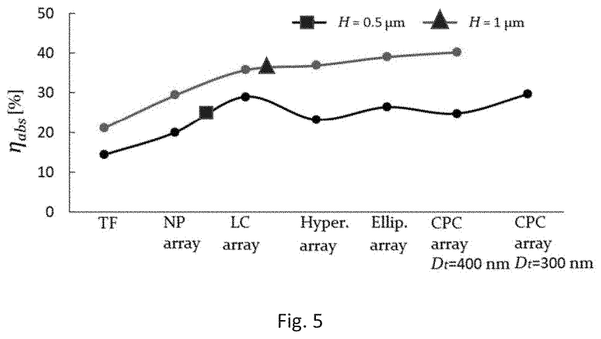

FIG. 5 compares the broadband absorption efficiencies between arrays containing various shapes of bodies. TF indicates a smooth film. NP indicates an array of nanopillar bodies. The LC array is an array containing truncated cones, each having a straight-line sidewall in cross section. A hyperbolic array is an array containing concave cones whose cross-section has a hyperbolic-like shape similar to a trumpet. An ellipsoidal array is an array containing truncated cones having a parabolic shape sidewall in cross-section. A CPB array is an array having compound parabolic shaped bodies (as discussed above). All the CPBs have subwavelength dimensions. In general, the simulations show that a replacement of a smooth film by a film having an NP array results in an efficiency (η_{abs}) increase of about 40% for both body heights (0.5 μm and 1 μm). A replacement of an NP array by a linear-cones array generates an additional nabs increase of 50% and 24% for 0.5 μm and 1 μm body heights, respectively. Furthermore, a replacement of a linear-cones array by, for example, a CPB-cones array, results in an additional efficiency η_{abs} increase of 13% when 1 μm height of CPBs are used in the array.

The examples above numerically demonstrate the efficient light trapping with arrays of subwavelength curved cones (i.e., cones having a curved sidewall when viewed in cross-section). It has been found that the arrays of the invention are characterized by low level of transmission, as compared, for example, with NP arrays that are known for their anti-reflection properties. The light trapping in the arrays of the invention is mainly due to efficient occupation of Mie modes, which is consistent with the inherent light concentration capabilities of individual curved bodies.

The inventors have found that similar advantages to those that are realized in truncated “convex cones” (i.e., cones having a convex sidewall in cross-section) can be obtained also in arrays of truncated “concave cones” (i.e., cones having a concave sidewall in cross-section), hereinafter also referred to as a “trumpet cones”). In a trumpet cone the shape of the sidewall is defined by a hyperboloid curve. As will be shown, the absorbing spectra of trumpet bodies are characterized by strong absorption peaks, some of which are just below the Yablonovitch limit. An enhanced light trapping is attributed by the inventors to an efficient occupation by the array of Mie modes, while the absorption enhancement at the near infrared is an order of magnitude higher than that of optimized nanopillar (NP) arrays.

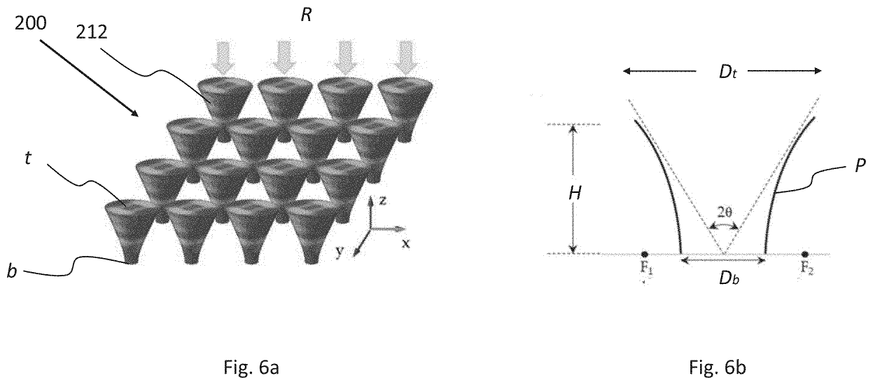

FIGS. 6a and 6b Illustrate an array 200 of subwavelength trumpet-shaped cones 212. In similarity to the case of the convex cones of FIGS. 2a and 2b, the base t having the larger diameter Dₜ faces the light radiation R, while the base b having the smaller diameter D_{b} faces away from the radiation direction. Typically, also in this case the cones are made of a semiconductor material, such as Silicon.

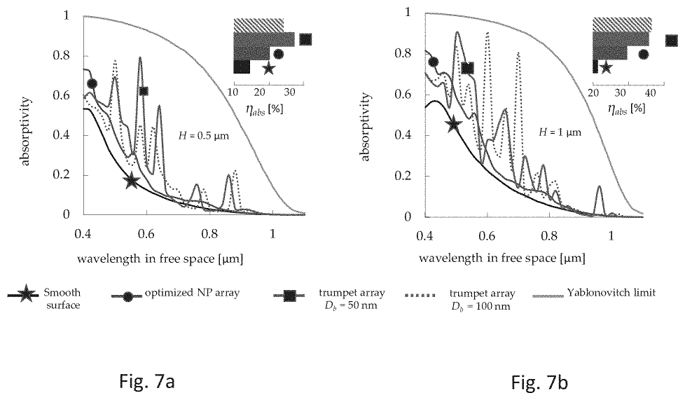

FIGS. 7a and 7b show the absorption spectra for: (a) free-floating trumpet arrays with H=0.5 μm and H=1 μm respectively (curves for D_{b}=50 nm and D_{b}=100 nm are shown in each graph, Dₜ=400 nm); (b) free-floating nanopillar arrays with H=0.5 μm and H=1 μm respectively (D_{b}=Dₜ=400 nm); (c) a thin film having a smooth film; and (d) The Yablonovitch limit is also shown. The array period was 500 nm. FIG. 7a shows the absorption for trumpet array having 0.5 μm height, while FIG. 7b similarly shows the absorption for trumpet array having 1 μm height. A comparison of the weighted absorption for each graph is also shown at the right side of the graph, respectively. Again, a transition from an optimized NP array into a trumpet array results in an emergence of strong absorption peaks; for example, for H=2 μm arrays (not shown) strong absorption peaks were visible in the spectral range >0.6 μm which are not present in the absorbing spectrum of the optimized NP array. For array heights of 0.5 μm and 1 μm (FIGS. 7a and 7b, respectively), η_{abs} demonstrates an almost monotonous efficiency increase with the decrease of D_{b} with an η_{abs} increase of 35% and 20% relative to NP array for arrays heights of 0.5 μm and 1 μm, respectively. Alternatively, for array height of 2 μm a maximum value of η_{abs} was recorded for D_{b}=200 nm which entails an η_{abs} improvement of 10% compared to that of the respective NP array. As can be seen, the absorption of a trumpet cone array exhibits not only higher efficiency compared to a nanopillar array, but the improvement is also seen in a broader spectra band.

It should be noted that each of the structures of the arrays in all the embodiments of the invention cause a spread of radiation (photons) throughout the entire area of the array (namely, within the cone bodies, as well as within areas between the bodies), not only within the volume of the cone bodies themselves. This is in contrast, for example, to the CPCs of the prior art, that cause concentration of light only at the “tip” of each truncated cone, respectively. Moreover, in one embodiment of the invention the array is made of a semiconductor material, such that the array itself absorbs radiation. In another embodiment, the array may be made of a dielectric material (such as Silicon Oxide), which is not a radiation absorbing material. In such a case, this dielectric array may receive the radiation, and will transfer it to a semiconductor layer at the back of the array, that will by itself absorb the radiation.

The curved cones (having convex or concave sidewalls in cross-section) of the invention can be fabricated within various types of semiconductor layers, such as Silicon, GaAs, Germanium, etc., thereby to form a very efficient light absorbing layer. The thickness of typical semiconductor layers, that can be used, for example, for trapping of solar radiation may be in the order of 2 μm to 500 μm. This is in view of the significant improvement in the light absorption that can be obtained in the arrays of the present invention. When fabricated within a semiconductor layer, the curved cones of the invention may also form a part of the photovoltaic cell, or any absorption-based photonic device. As will be discussed in more details hereinafter, the curved cones arrays of the invention may also be fabricated within an SOI structure. In one embodiment of the invention, the array of the present invention can be used as an anti-transmission layer. In another embodiment, when the array is coupled with an underlined substrate, the array can induce radiation absorption enhancement in the underlined substrate.

Silicon-on-Insulator (SOI) is a unique type of a silicon wafer which is widely used in the microelectronics industry to produce a variety of electronic components. The SOI typically has three layers: (a) A top Silicon substrate which is the only active layer of the structure. This layer has a typical thickness of a few μm (typically between 2 μm-20 um); (b) a middle Buried-Oxide layer; and (c) a bottom silicon handle layer. The bottom layer provides a mechanical strength and the BOX layer provide electrical isolation between the active top layer and the handle layer. Among various other applications, the SOI structure is utilized for advanced opto-electronic devices. However, the use for absorption-based opto-electronic devices is very limited, as the optical absorption at the active SOI layer is negligible in view of the very thin active layer (a few μm of thickness). More specifically, SOI devices are currently limited to photo-voltaic cells that can output voltage, not current, therefore, they are inadequate for power generation (such as in solar cells). The present invention shows that an array of subwavelength inverted-truncated cones within the very thin active layer can significantly increase the light absorption of the SOI device, which in turn can act as an opto-electronic power device. The truncated cones may be either linear or curved (concave or convex sidewall in cross section).

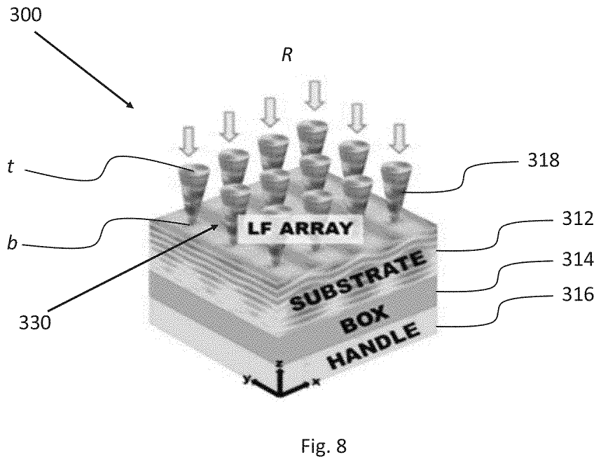

FIG. 8 schematically illustrates the structure of a SOI device 300 for absorbing light radiation, according to an embodiment of the present invention. As conventional, the SOI device 300 includes three layers: (a) a top active layer (substrate) 312 having a typical thickness in the order of between 2 μm-20 μm, made of Silicon; (b) a middle insulating layer, made of, for example, Buried-Oxide; and (c) a bottom handle layer which is typically made of Silicon. The SOI device 300 also includes an array 330 of inverted Silicon cones, that are embedded within the top active layer 312. The truncated cones are arranged such that their larger top base t faces the radiation R, and the bottom base b faces towards the middle layer 314.

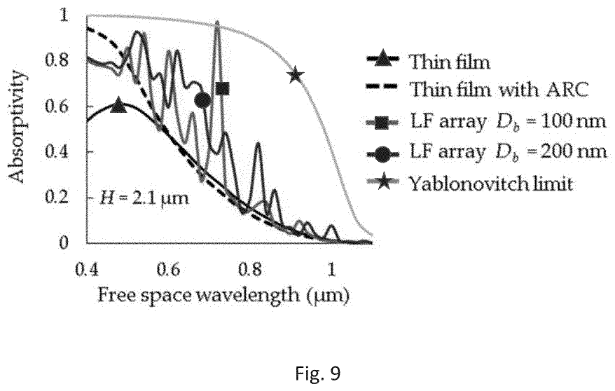

FIG. 9 shows the absorptivity spectra, as realized on an SOI wafer, for a 2.1 μm thin film (TF) with and without 40 nm Si3N4 anti-reflection coating (ARC), at two LF (“light funnels”—linear cones) arrays with bottom diameter (D_{b}) of 100 nm and 200 nm, respectively, and the Yablonovitch limit. A top diameter (Dₜ) of 400 nm, and a period of 500 nm were used. As can be seen, the LF array spectra are characterized by broadband absorption enhancement and strong absorption peaks that can potentially reach the Yablonovitch limit, in contrast with the curve showing the absorption spectra in a smooth (TF) film. As can be seen, the presence of an array 330 of inverted cones on top of the substrate (i.e., within the active layer) generates, for specific wavelengths, light trapping that approaches the Yablonovitch limit. The inventors have found that shorter arrays (i.e., of smaller height H) result in a higher absorptivity of the substrates, whereas higher arrays result in a higher contribution to the complex total absorptivity. The spectral range of 400 nm-1000 nm is characterized by low transmission due to efficient light trapping in the resonating substrate on account of the substrate-BOX interface and the BOX-handle wafer interface which reduces the probability of photons traversing the LF array-substrate complex. The transmissivity increases for wavelengths higher than ˜1000 nm as the efficiency of the bottom interfaces to reflect back impinging photons decreases, for longer wavelengths.

As can be realized, the significant increase of light absorption at the SOI device opens the path for the production of power electro-optical SOI devices. The above analysis and conclusions were obtained based on finite-difference time-domain (FDTD) electromagnetic calculations.

While the calculations above referred to an array of linear (LF) cones of various dimensions, it is expected to have similar, if not better results with an array 330 of curved sidewalls (concave or convex). This is based on the description above, that analysed the absorption of such arrays.

The fabrication of the SOI device based on the above structure, or any other structure described above, can be performed by use of conventional techniques that are common in the semiconductor industry.

The arrays of subwavelength inverted curved cones of the invention can form photovoltaic cells. This includes, for example, a photovoltaic cell with a PN junction in each of the curved inverted cones, such as axial junction or a radial junction, where one carrier type (electron or holes) is extracted from the bottom of the photovoltaic cell, and the other carrier type is extracted from a top section of the array. Alternatively, a back-contact configuration can be formed in which both electrons and holes are extracted using p-type and n-type diffusion areas at the bottom of the substrate. Such structures can be formed by use of standard techniques.

The advantages of applying the invention within an SOI structure is twofold. First, the presence of the SOI buried oxide (BOX) introduces two additional interfaces at the bottom of the substrate, the active SOI/BOX and the BOX/handle wafer interfaces, which increase the optical coupling between the array and the substrate. Second, SOI is an important technology which is utilized for various advanced optoelectronic devices.

In still another aspect, it has been surprisingly found by the inventors that the use of inverted truncated cones having straight sidewall lines (light funnels, LF) is advantageous not only in terms of light absorption compared to a thin film (TP) and nanopillar (NP) structures, but this shape is also very significantly advantageous in terms of the current collection and voltage provision from the cell. For example, while LF has been found to collect about 14% more photons compared to NP of same dimensions, the amount of current that can be collected from the LF is surprisingly increased by about 60%. This is in contrast to a realistic assumption that if an increase of 14% in photons absorption exists, an improvement of at most 14% (generally less) can be obtained in terms of the current collection. Same or even better results are expected for curved LFs.

### Further Discussion and Numerical Calculations

Photo-Current Improvements Previous studies demonstrated efficient broadband absorption of solar radiation with surface arrays of subwavelength inverted cones (LFs). The inventors used three-dimensional finite-difference time-domain electromagnetic calculations as well as three-dimensional device calculations to examine carrier extraction from photovoltaic cells that are composed of LF arrays on top of underlying substrates. For the selected geometry under examination, the inventors showed a broadband absorption enhancement of 14% for the LF photovoltaic cell compared with a cell-based compared to respective optically optimized nanopillar (NP) arrays. The inventors also showed that the nominal power conversion efficiency is 60% higher in the LF cell, due to the enhancement in both open-circuit voltage and short-circuit current. The higher open-circuit voltage in the LF cell is due to the higher injection of photocarriers, and the higher short-circuit current is a result of the unique LF geometry that supports efficient carrier extraction thanks to the naturally occurring gradients of the quasi-Fermi levels and minority carrier conductivity that allow for enhanced contact selectivity. The inventors believe that these observations pave the way for a new approach for carrier collection in photonic devices for energy applications.

The inventors numerically examined the carrier collection in photovoltaic cells based on LF arrays. The inventors specifically considered a photovoltaic cell based on LF arrays on top of a thin substrate with an axial configuration.

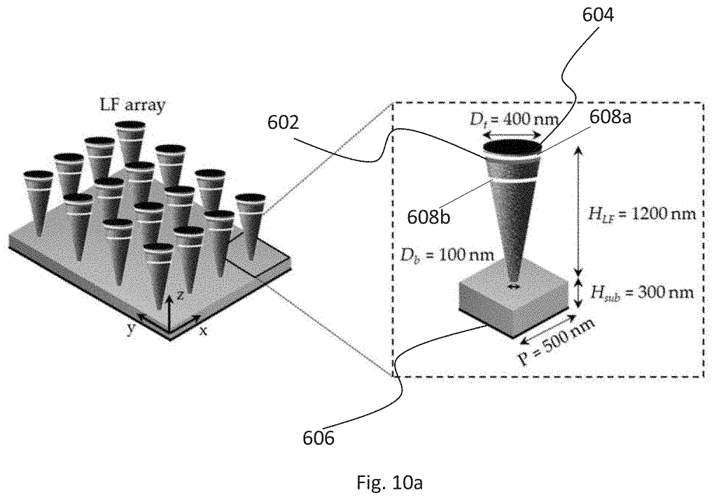

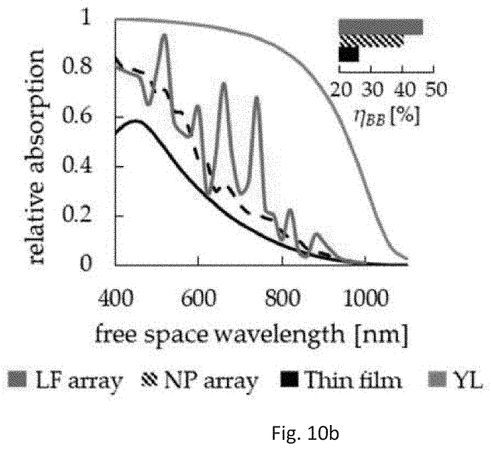

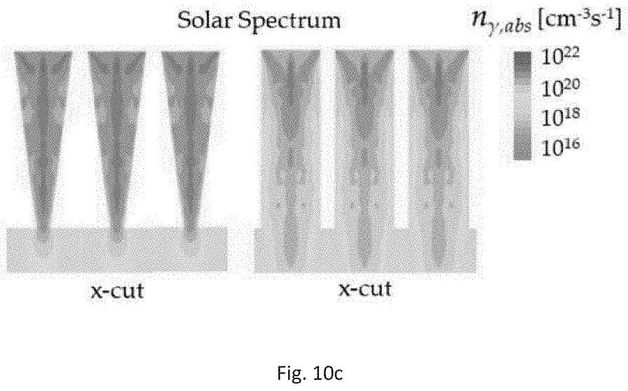

FIG. 10a illustrates an LF array on top of an underlying substrate. The total height of the array-substrate complex was set to 1.5 mm and the periods of both the NP and the LF arrays were set to 500 nm with a top diameter (Dₜ) of 400 nm, to comply with optically optimized geometry for the absorption of solar radiation. The geometry that provides the highest broadband absorption for both the NP array-substrate complex (henceforth, the NP complex) and LF array-substrate complex (henceforth, the LF complex) is a substrate thickness of 0.3 mm and an array height of 1.2 mm (not shown). Furthermore, the broadband absorption of the LF complex is maximized for an LF bottom diameter (D_{b}) of 100 nm. The selected dimensions are for a single unit cell in an LF array are indicated in FIG. 10a. Also, the electrical configuration is shown where a shallow axial junction 602 is considered with a 20 nm n-type phosphorus-doped emitter and a p-type boron-doped absorber with a bottom hole contact. The top emitter contact is indicated by 604 and the bottom absorber contact is indicated by 606. The extent of the depletion region is indicated by 608a-608b. To focus on the specific contribution of the LF geometry to carrier collection the inventors did not consider an anti-reflective coating (ARC), a bottom reflector, and a back-surface field (BSF). FIG. 10b presents the absorption spectra of the selected LF complex, the NP complex, a thin film of 1.5 mm thickness, and the respective Yablonovitch limit (YL). The inset in FIG. 10b presents the broadband absorption efficiency (η_{BB}) with a 14% enhancement of the LF complex over the optically optimized NP complex. FIG. 10c shows the absorbed photon density (η_{γ,abs}) under the illumination of AM 1.5G solar radiation for both the LF and NP complexes, in which the stronger excitation of the LF complex is evident.

In the following photovoltaic analysis, the inventors constructed LF and NP photovoltaic cells from single-unit cells in the respective complexes, as presented in the inset in FIG. 10a for the LF cell.

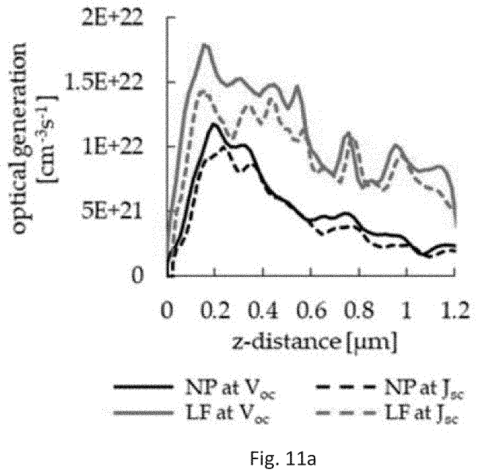

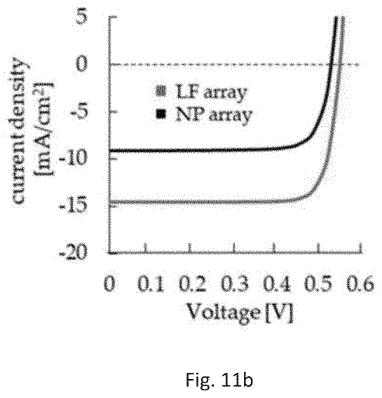

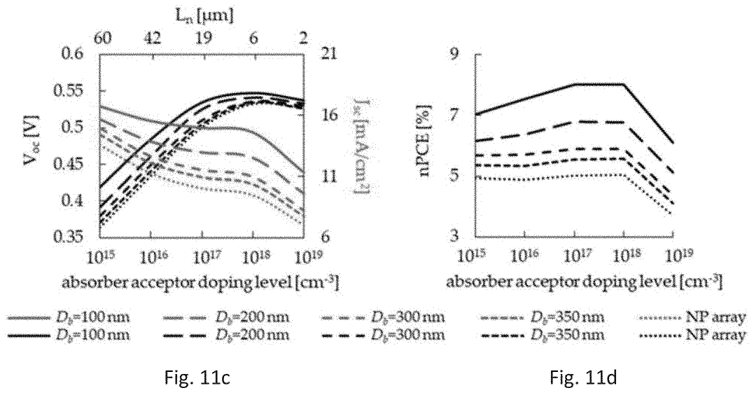

FIG. 11a shows the optical generation profiles along the vertical axes of the NP and LF complexes under both J_{sc} and V_{oc} conditions, where the higher optical generation in the LF complex is evident. FIG. 11b presents current-voltage (I-V) curves for an absorber acceptor doping level (NA) of 10¹⁸ cm⁻³ for both NP and LF photovoltaic cells, where the photocurrent enhancement of the LF cell is a direct consequence of the enhanced optical generation. Next, the inventors followed the transition from an NP cell into an LF cell by gradually decreasing the NP bottom diameter from D_{b}=400 nm to D_{b}=350 nm, 300 nm, 200 nm, and 100 nm. The absorption and the optical generation for each geometry were calculated (not shown). FIG. 11c shows the dependency of J_{sc} and V_{oc} on N_{A} for different D_{b} values. A gradual increase in both V_{oc} and J_{sc} is noticeable with the decrease in D_{b} for the full range of N_{A} values. It can be seen that V_{oc} reaches a maximum for N_{A}=10¹⁸ cm⁻³ which is a direct consequence of the saturation current-dependency on N_{A} and minority carrier lifetimes which also depend on N_{A}. The respective electron diffusion lengths (Lₙ) are also presented in FIG. 11c. FIG. 11d presents the dependency of the nominal power conversion efficiency (nPCE), defined as J_{sc}×V_{oc}/Pᵢₙ where Pᵢₙ is the power of the solar spectrum at AM 1.5 G, on N_{A} for all the considered D_{b} values. The nPCE values of all cells peak at N_{A}=10¹⁷ cm⁻³. The highest nPCE=8% is obtained for the smallest D_{b}=100 nm as compared with the NP cell with an nPCE of 5% which reflects an nPCE enhancement of 60%. This is surprising as the η_{BB} enhancement was only 14%. To understand the origin of the 60% nPCE enhancement, the inventors next carefully examined the behavior of J_{sc} and V_{oc} of both the LF and NP cells.

The V_{oc} enhancement of the LF cell over the NP cell decreases with an increase in N_{A}, with the highest value of 15% for N_{A}=10¹⁵ cm⁻³, and with a corresponding J_{sc} enhancement of 23% (see FIG. 11c). V_{oc} is equal to the splitting of the quasi-Fermi levels (ε_{fc}−ε_{fv}, where ε_{fc} is the electron quasi-Fermi level, and ε_{fv} is the hole quasi-Fermi level), between the top emitter electron contact and the bottom absorber hole contact, and it is equal to the free energy delivered to the load. FIGS. 12a and 12b present the energy band diagrams along the vertical axes of the LF cell and the NP cell for N_{A}=10¹⁵ cm⁻³ and 10¹⁹ cm⁻³, respectively. The cross-sections of LF and NP cells above the band diagrams visualize the considered orientation. The V_{oc} values extracted from the energy band diagrams for N_{A}=10¹⁵ cm⁻³ are 419 mV and 364 mV for the LF and the NP cells, respectively, and similarly for N_{A}=10¹⁹ cm⁻³ the V_{oc} values are 537 mV and 527 mV. The V_{oc} values extracted from the energy band diagrams are in agreement with the V_{oc} values extracted from the I-V curves (FIG. 11c). Next, the inventors examined the origin of the quasi-fermi level splitting and its dependency on N_{A}. For a p-type absorber (1) V_{oc}=kT ln(1+Δₙₑ/nₑ₀), where k is the Boltzmann constant, T is the cell temperature) (300 K°, Δnₑ is the injected photoelectron density and nₑ₀ is the equilibrium electron density. FIGS. 12c and 12d show the Δnₑ profiles where for N_{A}=10¹⁵ cm⁻³ the densities are higher than for N_{A}=10¹⁹ cm⁻³ due to the doping-dependent lifetimes. Also, while for N_{A}=10¹⁵ cm⁻³ Δne of the LF is significantly higher, for N_{A}=10¹⁹ cm⁻³ the Δnₑ values of the LF and NP are similar.

FIGS. 12e and 12f show the respective calculated spatially resolved V_{oc} profile for a p-type absorber according to (1). The origin of the higher V_{oc} of the LF cell for N_{A}=10¹⁵ cm⁻³ is apparent. The higher broadband absorption and the optical generation of the LF cell entail a higher population of electron minority carriers in the absorber, which for most of the 1D profile is about one order of magnitude higher than that in the NP cell. This considerably higher excitation of the absorber directly translates into a higher V_{oc}. This difference in absorber-excited minority carriers disappears for N_{A}=10¹⁹ cm⁻³ due to the higher Shockley-Read-Hall (SRH) recombination. However, a higher N_{A} presents a higher V_{oc} due to the absorber nₑ₀ which is three orders of magnitude smaller for N_{A}=10¹⁹ cm⁻³. The enhanced absorber photoelectron density for N_{A}=10¹⁵ cm⁻³ is also apparent in the 2D cross-section presented in FIG. 12a. Therefore, the higher V_{oc} at N_{A=10}¹⁵ cm⁻³ in the LF cell is a combination of higher carrier injection and lower level of recombination.

The J_{sc} enhancement of the LF cell compared with the NP cell increases with N_{A} from 24% to 61% for N_{A}=10¹⁵ cm⁻³ to 10¹⁹ cm⁻³, respectively (see FIG. 11c). The generation of photocurrent reflects the conversion efficiency of chemical energy into electrical energy. The electron current is described by Jₑ=> [symbol] ₑ/q grad(ε_{fn}), where grad(ε_{fn}) is the gradient of the electron quasi-fermi level, q is the elementary charge and [symbol] ₑ is the electron conductivity equal to nₑqμₑ where nₑ is the electron density and μₑ is the electron mobility. Hence a higher [symbol] ₑ and grad(ε_{fn}) along the electron path towards the emitter contact will induce greater emitter selectivity towards electrons and therefore a higher Jₑ.

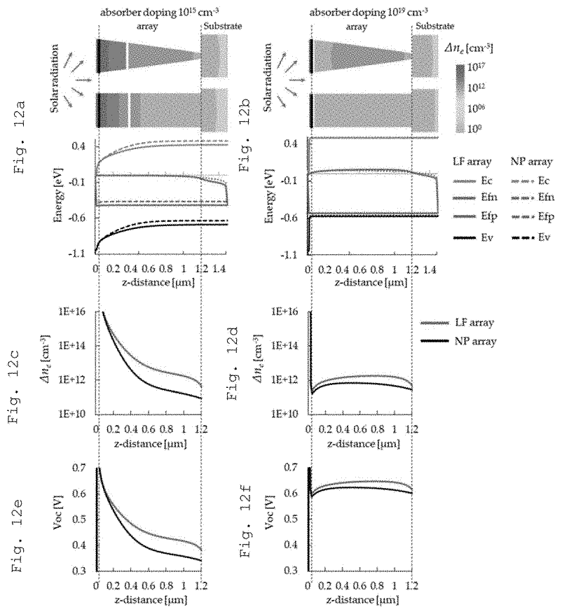

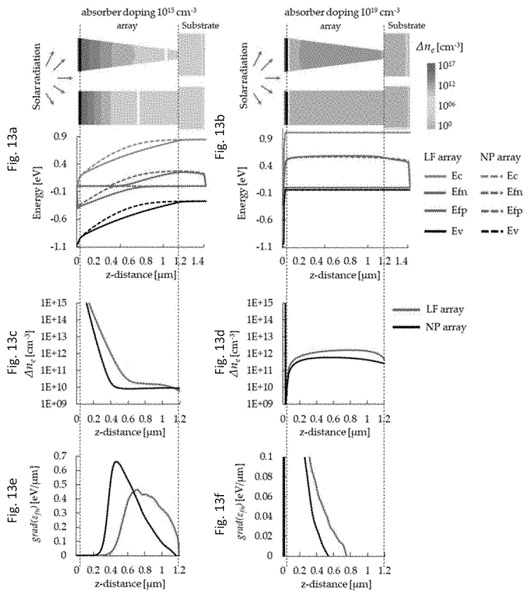

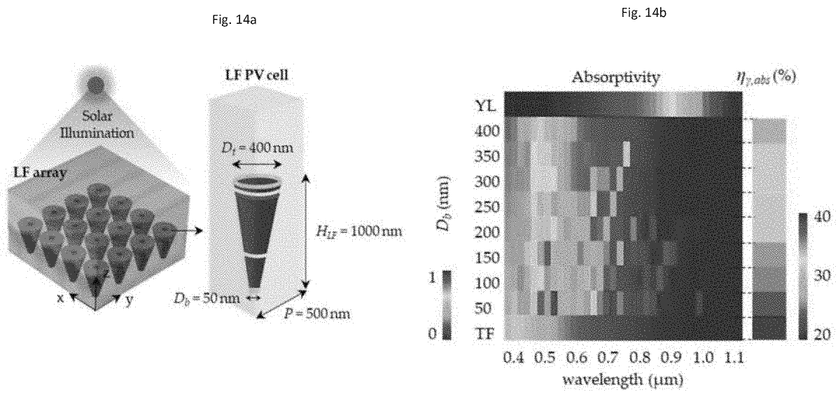

FIGS. 13a and 13b show the energy band diagrams of the NP and LF cells under J_{sc} conditions for N_{A}=10¹⁵ cm⁻³ and 10¹⁹ cm⁻³, respectively. FIGS. 13c and 13d show the respective nₑ which is linearly proportional to [symbol] ₑ, and FIGS. 13e and 13f show the respective grad(ε_{fn}) for which it is positive. For N_{A}=10¹⁵ cm⁻³ nₑ, and hence [symbol] ₑ in the LF cell increases towards the emitter contact more appreciably which provides an enhanced emitter selectivity towards electrons in the LF cell compared with that of the NP cell. grad( [symbol] _{fn}) for N_{A}=10¹⁵ cm⁻³ is positive for both cells, which indicates a decrease in ε_{fn} towards the emitter, but it is not necessarily higher in the LF cell as shown in FIG. 13e. Overall for N_{A}=10¹⁵ cm⁻³ the combined effect of nₑ and grad(ε_{fn}) results in 24% J_{sc} enhancement. For N_{A}=10¹⁹ cm⁻³ (FIG. 13f) both [symbol] ₑ and grad(ε_{fn}) (i.e. where grad(ε_{fn})>0) are higher in the LF cell. Therefore, the combined enhancement of [symbol] ₑ and grad(ε_{fn}) results in an overall J_{sc} enhancement of 61% in the LF cell compared with the NP cell. Importantly, the origin of the higher grad(ε_{fn}) in the LF cell is due to the gradient in the electron chemical potential which is due to the higher [symbol] ₑ at the LF bottom part which is a direct consequence of the unique LF inverted geometry.

### Photo-Voltage Improvements

Surface arrangements of subwavelength formations have been extensively discussed in the context of photo-current enhancement for photovoltaic (PV) applications. The following numerical calculations demonstrate improvement in the photo-voltage management based on arrays of inverted silicon cones (LF) arrays. The inventors examined the transition from an optimized nanopillar (NP) array into an LF array in terms of photovoltage improvement, and demonstrate that a decrease in the NP bottom diameter (D_{b}) is accompanied by an increase in open-circuit voltage (V_{oc}). The highest photo-voltage enhancement was recorded for the smallest considered D_{b}=50 nm with a V_{oc} increase of 75 mV and reflects a 22% V_{oc} enhancement compared with the NP V_{oc}. The inventors showed that this V_{oc} increase is due to a 250% increase in the excitation level and that the spatially-resolved excitation level of the array-nested LFs is more than two orders of magnitude higher than the highest spatially-resolved excitation level in the array-nested NPs. Finally, the inventors showed that the suggested photo-voltage management entails almost a factor of two increase in the nominal power conversion efficiency upon the transition from an NP PV cell into an LF PV cell.

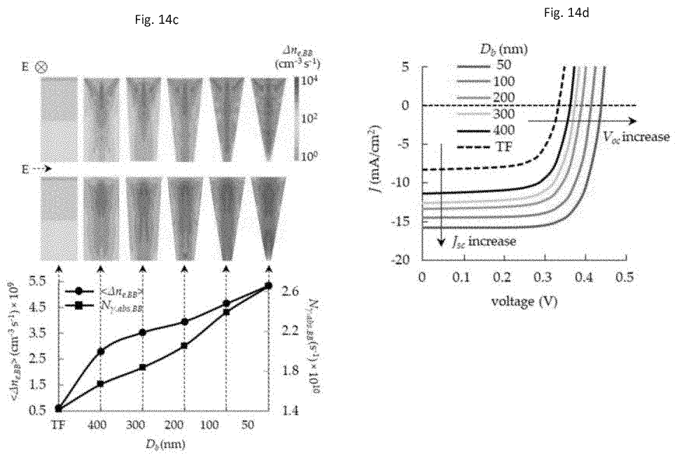

FIG. 14a illustrates a free-floating square-tiled silicon LF array. The analysis included a transformation of a unit cell in the array into a PV cell, as indicated in FIG. 14a. The geometrical parameters that were considered are indicated, where Dₜ and D_{b} are the LF top and bottom diameters, respectively, H_{LF} is the array height, and P is the period. A PV cell that is based on a unit cell of the LF geometry is referred to as an LF PV cell, and similarly, nano-pillar (NP) PV cells and thin-film (TF) PV cells are defined. The silicon PV cells were composed of a shallow degenerated phosphorus-doped n-type emitter extending from the top of the LF to the axial metallurgical homogeneous p-n junction located 20 nm below, and a p-type absorber below it. The structure of the cell in FIG. 14a is substantially the same as the structure of the cell of FIG. 10a. FIG. 14b is a color map presenting the dependency of the absorptivity spectra on D_{b}.

FIG. 14c shows the D_{b} dependency of the spatial distribution of the broadband excitation level (Δn_{e,BB}) in an LF PV cell under AM1.5G illumination for P=0.5 μm. In the following discussion the average excitation level, <Δn_{e,BB}>, of each individual geometry is defined as the total number of broadband absorbed photons (N_{γ,abs,BB}) divided by the structure volume. The cross-sectional graphs show that N_{γ,abs,BB} increases as the LF D_{b} decreases, which means that in LFs more photons are absorbed with less material compared to a corresponding NP array. Moreover, <Δn_{e,BB}> increases upon a transition from TF to NP and further in the transition to the LF geometry, with decreasing D_{b}. Therefore, upon transition to the LF geometry not only N_{γ,abs,BB} increases (which induces higher photo-current), but also <Δn_{e,BB}> increases (which induces higher photo-voltage), as discussed below.

FIG. 14c shows the distribution of Δ_{ne,BB} for various values of D_{b}. The direction of the impinging electric field is indicated. <Δ_{ne,BB}> and N_{γ,abs,BB} for each of the geometries are presented below the cross-sections. FIG. 14d shows the respective D_{b} dependent current density-voltage (J-V) curves for absorber doping level (Nₐ) of 10¹⁵ cm⁻³. The increase of J_{sc}, with the decrease of D_{b} is apparent and consistent with the elevated N_{γ,abs,BB} values in FIG. 14c, namely, a J_{sc}, increase of almost 40% was recorded for the D_{b}=50 nm LF PV cell compared to the NP PV cell. More importantly, an 8% V_{oc} enhancement was observed upon the transition from a TF PV cell to an NP PV cell, in contrast with the transition from a TF PV cell to a D_{b}=50 nm LF PV cell with a V_{oc} enhancement of 32%. The inventors observed that LF arrays not only generate high photo-currents due to high N_{γ,abs,BB}, but also that the elevated minority carrier excitation level motivated by the unique LF inverted geometry induces enhanced photo-voltage.

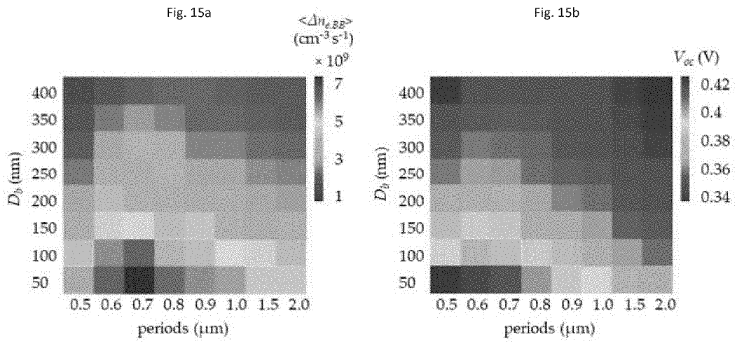

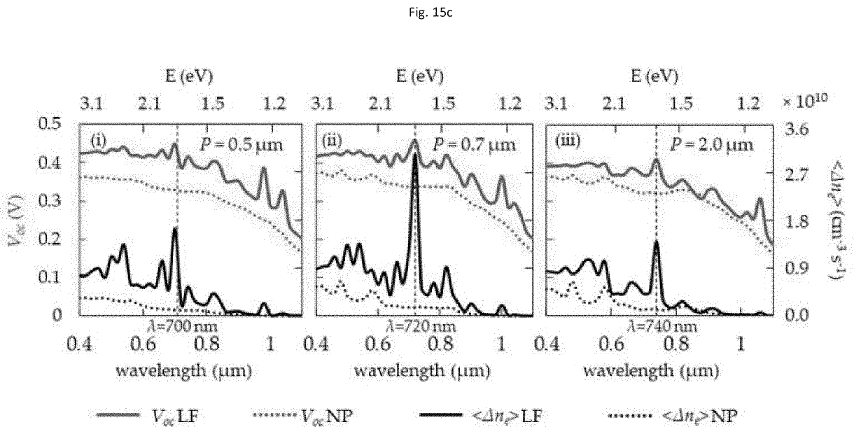

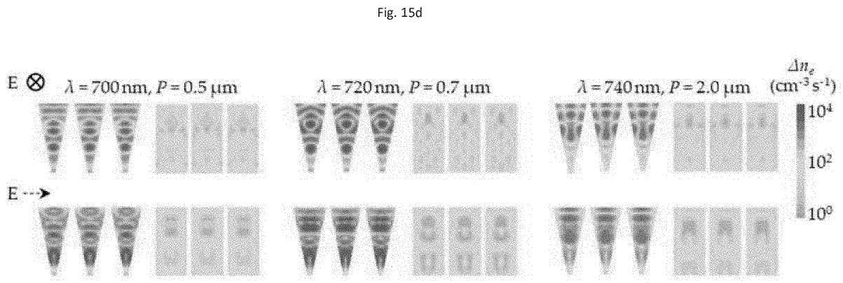

FIG. 15a shows the dependency of <Δn_{e,BB}> on P and D_{b}, for an LF PV cell. The maximum <Δn_{e,BB}> value of ˜10⁹ cm⁻³s⁻¹ implies weak excitation in the case of a p-type absorber with Nₐ=10¹⁵ cm⁻³. It is apparent that <Δn_{e,BB}> is higher for smaller D_{b} values, and the highest <Δn_{e,BB}> value is recorded for D_{b}=50 nm which is three times greater than the highest <Δn_{e,BB}> for an NP (D_{b}=400 nm) PV cell value, both for P=0.7 μm. Also, the variation of the NP PV cell <Δn_{e,BB}> with P is very weak, whereas the LF PV cell <Δn_{e,BB}> depends strongly on P. This <Δn_{e,BB}> dependency on the period vanishes as the D_{b} converges to an NP D_{b} value of 400 nm.

FIG. 15b shows the respective V_{oc} values that were extracted from the numerically calculated J-V curves. The highest LF PV cell V_{oc}=418 mV is calculated for D_{b}=50 nm at P=0.5 μm, and the highest NP PV cell V_{oc}=352 mV was calculated for P=0.7 μm which reflects a V_{oc} enhancement of 20%. The evident correlation between V_{oc} and <Δn_{e,BB}> is expected and agrees with the weak homogeneous excitation approximation (1) V_{oc}=kT/q ln(1+<Δn_{e,BB}>/n₀), where k is the Boltzmann constant, q is the elementary charge, T is 300K° cell temperature, and n₀ is the equilibrium electron density (for a p-type absorber). FIG. 15c shows the spectrally-resolved V_{oc} and <Δₙₑ> for an NP PV cell and an LF PV cell for P=0.5, 0.7 and 2 μm for the indicated wavelengths. The interplay between V_{oc} and <Δn_{e,BB}> is also manifested spectrally as shown in FIG. 15c which presents the spectrally-resolved <Δnₑ> and V_{oc} for both the NP and the LF PV cells (D_{b}=50 nm) for P=0.5, 0.7, and 2 μm, respectively. It was also observed that the <Δnₑ> and the V_{oc} spectra of the LF and the NP PV cells diverge more dramatically for lower P values where the LF PV cell values of <Δnₑ> and V_{oc} are appreciably higher as also visible in the broadband response of FIGS. 15a and 15b. FIG. 15d shows the spatial distribution of Δnₑ for the wavelengths marked in FIG. 15c, which support the significantly higher <Δnₑ> spectral peaks for the LF PV cell compared with the corresponding NP PV cell peaks in FIG. 15c. It can also be noticed that the highest value of the spatially-resolved Δnₑ is in the range of 10² cm⁻³s⁻¹ for the NP PV cell whereas Δnₑ reaches values in the range of 10⁴ cm⁻³s⁻¹ for the LF PV cell.

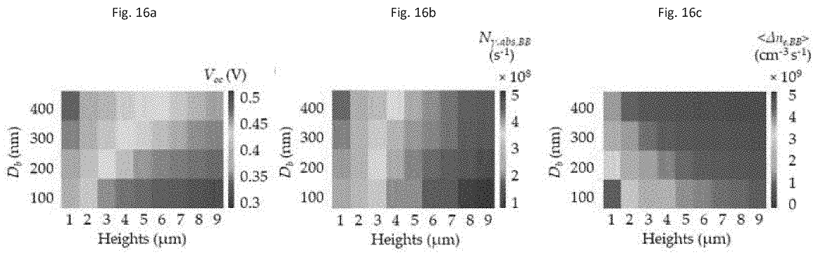

FIGS. 16a-16c show the V_{oc} dependency on PV cell height. As described above, the optical absorption of the PV cell is determined by calculations performed at the array-level. P=0.5 μm was considered as a study case. FIG. 16a shows the D_{b} and P dependency of V_{oc} values that are extracted from the numerically-calculated J-V curves. FIG. 16b shows the corresponding N_{γ,abs,BB}, and FIG. 16c shows the corresponding <Δn_{e,BB}>. As expected, the highest V_{oc} values were recorded for the 9 μm PV cells; the highest V_{oc} was recorded for the 9 μm LF PV cell with D_{b}=100 which is 9.7% higher than the 9 μm NP PV cell. The superior V_{oc} for higher arrays is accounted for the higher absorption, as clearly shown in FIG. 16b. However, the correspondence between FIGS. 16a and 16b is misleading, as the N_{γ,abs,BB} variation between the 9 μm cells is only about 8%. The variation between these cells is due to the increased <Δn_{e,BB}> in the 9 μm LF cell, which is 150% higher than in the NP PV cell. In fact, the greatest V_{oc} enhancement upon the transition from an NP PV cell into an LF PV cell is calculated for a 1 μm cell height, as the sharper sidewall angle induces a greater enhancement of <Δn_{e,BB}> (180%), which entails a V_{oc} enhancement of 14.3%. The effect of <Δn_{e,BB}> is reflected in FIG. 16c, which clearly shows that the highest <Δn_{e,BB}> enhancement occurs for an array height of 1 μm due to the sharper sidewall angle that results in a higher optical excitation level.

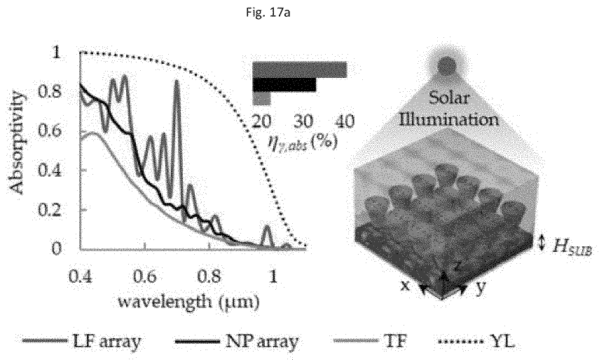

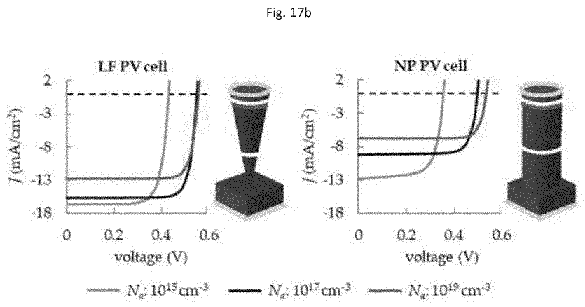

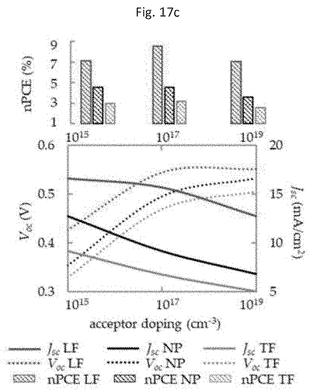

To further elucidate the potential of the proposed photo-voltage management, the inventors have considered arrays on top of an underlying 200 nm thick substrates (H_{SUB}). FIG. 17a shows the absorptivity spectrum of a D_{b}=50 nm LF array with an underlying 200 nm substrate (H_{SUB}). The rest of the geometrical parameters are identical to those of FIG. 14a. The inset presents an illustration of the LF array on top of the substrate. The corresponding absorptivity spectrum of an NP array with a 200 nm underlying is shown as well. Also, the YL spectrum for a 1.2 μm film and the absorptivity spectrum of a 1.2 μm TF are presented as well. The respective ηγ,abs are shown in the inset. As displayed in FIG. 17a, the other geometrical parameters are the same as indicated in FIG. 14a (P=0.5 μm). FIG. 17a also shows the absorptivity spectra of a D_{b}=50 nm LF array, an NP array, the corresponding TF, and the YL. The corresponding calculated η_{γ,abs} is indicated in the inset. Next, following the methodology above, a PV cell that is based on the array single-unit cell, with the additional underlying substrate, was formed, and a PV performance comparison between the D_{b}=50 nm LF PV cell and the NP PV cell was carried out. FIG. 17b illustrates the LF PV cell and the NP PV cell, as well as the respective numerically-calculated J-V curves for Nₐ=10¹⁵, 10¹⁷ and 10¹⁹ cm⁻³. FIG. 17c presents the extracted values of V_{oc}, J_{sc}, and the nominal PCE (nPCE), assuming a unity filling factor.

The highest V_{oc} of the LF PV cell was obtained for Nₐ=10¹⁷ cm⁻³ and 10¹⁹ cm⁻³, which is slightly higher than the highest V_{oc} of the NP PV cell that was obtained for Nₐ=10¹⁹ cm⁻³. This is of utmost importance, as it means that the LF PV cell V_{oc} can attain its maximal value for a lower Nₐ. This observation has a direct implication on J_{sc}, as, inherently, the minority carrier lifetimes in silicon are determined by the non-radiative SRH recombination which concludes shorter minority carrier lifetimes as the doping level increases.

Therefore, the highest NP PV cell nPCE can only be obtained at lower doping levels (either Nₐ=10¹⁵ or 10¹⁷ cm⁻³), because for Nₐ=10¹⁹ cm⁻³, which provides the highest V_{oc}, J_{sc} values are very small due to doping-dependent SRH. This observation can clearly be seen in FIG. 17c. On the other hand, the maximal LF PV cell V_{oc} can be reached at lower Nₐ, 10¹⁷ cm³ in the present study case, due to the enhanced excitation level supported by the unique LF geometry. Therefore, to maximize the LF PV cell nPCE, there is no necessity to compromise on V_{oc}, as nPCE is determined by the highest possible V_{oc} which also supports high J_{sc} values. This situation cannot be accomplished with an NP PV cell, for example, and can only be accomplished with PV cells that provide higher levels of excitation as in the case of the LF PV cell. Overall, this leads to an LF PV cell nPCE which is almost twice higher (90% enhancement) than the maximal NP PV cell nPCE.

While some of the embodiments of the invention have been described by way of illustration, it will be apparent that the invention can be carried into practice with many modifications, variations, and adaptations, and with the use of numerous equivalents or alternative solutions that are within the scope of a person skilled in the art, without departing from the spirit of the invention, or the scope of the claims.

1. An array for absorbing light radiation, comprising a plurality of subwavelength inverted cones that are arranged on a layer, each cone having a curved sidewall in cross-section.

2. The array of claim 1, used in an absorption-based optical device.

3. The array of claim 1, wherein each of the cones is a truncated cone which is inverted such that its wider base faces the incoming radiation.

4. The array of claim 1, wherein the curved sidewall is convex.

5. The array of claim 4, wherein the convex sidewall has a compound parabolic body shape.

6. The array of claim 4, wherein convex sidewall has a parabolic shape.

7. The array of claim 1, wherein the curved sidewall is concave.

8. The array of claim 7, wherein the curved concave sidewall has a trumpet-like shape.

9. The array of claim 1, wherein the period between the cones is in the subwavelength light range.

10. The array of claim 1, wherein the period between the cones is substantially in the order of a wavelength of an impinging illumination.

11. The array of claim 1, which is fabricated from a semiconductor material.

12. The array of claim 11, wherein the semiconductor material is selected from Silicon, GaAs, or Germanium.

13. The array of claim 1, wherein each of the cones, together with the layer, forms a photovoltaic cell.

14. The array of claim 1, which is configured to absorb radiation in a specific spectrum or wavelength of light.

15. The array of claim 1, which is configured to a limited range of spectral radiation.

16. The array of claim 1, which is fabricated from a dielectric material, said array causing an absorption of radiation in an underlying layer made from a semiconductor material.

17. The array of claim 1, further comprising an anti-reflection coating.

18. An SOI structure for absorbing light radiation, said structure comprising within a Silicon layer in the structure an array of a plurality of subwavelength inverted cones.

19. The SOI structure of claim 18, further comprising an insulating buried oxide layer and a handle layer.

20. An absorption-based optical device, comprising an array for absorbing light radiation, said array comprising a plurality of subwavelength inverted cones that are arranged on a layer, each cone having a curved sidewall in cross-section.

21. The absorption-based optical device of claim 20, which is configured to absorb broadband light.

22. The absorption-based optical device of claim 20, further comprising a filter to limit the absorption to a specific spectrum or wavelength of light.
